(19) United States
(12) Patent Application Publication
(10) Pub. No.: US 2026/0333935 A1
(43) Pub. Date: Oct. 22, 2026

(54) LIGHT DETECTION ELEMENT AND METHOD FOR MANUFACTURING LIGHT DETECTION ELEMENT

(71) Applicant: HAMAMATSU PHOTONICS K.K., Hamamatsu-shi (JP)

(72) Inventors: Wei DONG, Shizuoka (JP); Hiroyasu FUJIWARA, Shizuoka (JP); Shigeo HARA, Shizuoka (JP)

(73) Assignee: HAMAMATSU PHOTONICS K.K., Hamamatsu-shi (JP)

(21) Appl. No.: 19/566,024

(22) Filed: Mar. 13, 2026

(30) Foreign Application Priority Data
Mar. 18, 2025 (JP) 2025-043548

(51) Int. Cl. H10F 77/14; H10F 30/22; H10F 39/10; H10F 71/00; H10F 77/1226

(52) U.S. Cl. CPC H10F 77/147; H10F 30/22; H10F 39/107; H10F 71/1215; H10F 71/128; H10F 77/1226

(57) ABSTRACT

A light detection element including a substrate having a main surface; an underlayer formed of a simple first material containing a first element and having a single crystal structure; and a light absorbing layer having a single crystal structure formed of a second material that is a compound of the first element and a second element, in which the underlayer includes a first portion, and a second portion located outside the light absorbing layer, the light absorbing layer is in contact with a first surface of the first portion on a side opposite to the substrate, and in the thickness direction of the substrate, a height from the main surface to a second surface of the second portion opposite to the substrate is equal to or greater than a height from the main surface to the first surface.

### TECHNICAL FIELD

One aspect of the present disclosure relates to a light detection element and a method for manufacturing the light detection element.

### BACKGROUND

Patent Document 1 (Japanese Unexamined Patent Publication No. 2004-189505) and Non-Patent Document 1 (Kaoru Toko, Ryota Yoshimine, Kenta Moto, and Takashi Suemasu, “High-hole mobility polycrystalline Ge on an insulator formed by controlling precursor atomic density for solid-phase crystallization”, Scientific Reports, published online: 5 Dec. 2017) each describe an example of a method for forming a semiconductor layer having a single crystal structure. In the conventional methods as described in Patent Document 1 and Non-Patent Document 1, an amorphous semiconductor is formed on a semiconductor single crystal, a heat treatment is performed on the semiconductor single crystal and the amorphous semiconductor, and crystallization is performed by solid phase growth of the amorphous semiconductor according to the crystal orientation of the semiconductor single crystal to thereby form a new semiconductor single crystal. The single crystallized semiconductor layer can be used as a light absorbing layer in a light detection element such as a SWIR light receiving element.

### SUMMARY

However, in the conventional methods described above, surface roughness (irregularity structure) may occur on the light absorbing layer after the heat treatment. When surface roughness occurs on the light absorbing layer, the detection performance of the light detection element using the light absorbing layer may deteriorate. Therefore, a technique for preventing surface roughness of the light absorbing layer and improving the detection performance of the light detection element is desired.

An object of one aspect of the present disclosure is to provide a light detection element capable of improving detection performance, and a method for manufacturing such a light detection element.

A light detection element according to an aspect of the present disclosure is [1] “a light detection element including a substrate having a main surface; an underlayer formed, on the main surface, of a simple first material containing a first element and having a single crystal structure; and a light absorbing layer having a single crystal structure formed, on the underlayer, of a second material that is a compound of the first element and a second element different from the first element, in which the underlayer includes a first portion located between the substrate and the light absorbing layer, and a second portion located outside the light absorbing layer and adjacent to the first portion when viewed in a thickness direction of the substrate, the light absorbing layer is in contact with a first surface of the first portion on a side opposite to the substrate, and, in the thickness direction of the substrate, a height from the main surface to a second surface of the second portion opposite to the substrate is equal to or greater than a height from the main surface to the first surface”.

In the light detection element, the underlayer includes a first portion located between the substrate and the light absorbing layer, and a second portion located outside the light absorbing layer and adjacent to the first portion when viewed in a thickness direction of the substrate. That is, the second portion of the underlayer is formed outside the light absorbing layer when viewed in the thickness direction of the substrate. In this case, in the process of manufacturing the light detection element, for example, when the light absorbing layer in an amorphous state is single-crystallized by heating through light irradiation, the second portion absorbs light to generate heat. Due to the generated heat, a boundary portion of the light absorbing layer with the second portion when viewed in the thickness direction of the substrate (outer edge of the light absorbing layer) reaches the eutectic temperature earlier than the other portions. Accordingly, a single crystal nucleus is formed at the boundary portion, and single crystallization proceeds from the nucleus as a starting point toward the central portion of the light absorbing layer (from the outer edge toward the central portion of the light absorbing layer). This can prevent surface roughness of the light absorbing layer. Further, in the thickness direction of the substrate, a height from the main surface of the substrate to the second surface of the second portion is equal to or greater than a height from the main surface of the substrate to the first surface of the first portion. This facilitates the transfer of the heat generated in the second portion to the boundary portion of the light absorbing layer with the second portion. Therefore, a single crystal nucleus is easily formed at the boundary portion. Thus, according to the light detection element, surface roughness of the light absorbing layer is prevented, and the detection performance can be improved.

The light detection element according to an aspect of the present disclosure may be [2] “the light detection element according to described above, in which, in the thickness direction of the substrate, the height from the main surface to the second surface is greater than the height from the main surface to the first surface”. In this case, the boundary portion of the light absorbing layer with the second portion as viewed in the thickness direction of the substrate (outer edge of the light absorbing layer) can be more reliably heated, and surface roughness of the light absorbing layer can be further prevented.

The light detection element according to an aspect of the present disclosure may be [3] “the light detection element according to or [2] described above, in which the light absorbing layer has a side surface connecting a surface of the light absorbing layer on a side opposite to the substrate and a surface of the light absorbing layer on a side of the substrate, and the second portion is in contact with the side surface”. In this case, the boundary portion of the light absorbing layer with the second portion as viewed in the thickness direction of the substrate (outer edge of the light absorbing layer) can be more reliably heated, and surface roughness of the light absorbing layer can be further prevented.

The light detection element according to an aspect of the present disclosure may be [4] “the light detection element according to any one of [1] to [3] described above, in which the first element is a group 14 element, and the second element is a group 14 element different from the first element”. In this case, since both the first element and the second element are group 14 elements, the band energy of the light absorbing layer formed of the second material which is a compound of the first element and the second element can be controlled, so that light having a desired wavelength can be absorbed by the light absorbing layer.

The light detection element according to an aspect of the present disclosure may be [5] “the light detection element according to any one of [1] to [4] described above, in which the first element is Ge, and the second element is Sn”. In this case, the light absorbing layer can function as a layer that absorbs light in a short wave infrared (SWIR) region.

The light detection element according to an aspect of the present disclosure may be [6] “the light detection element according to any one of [1] to [5] described above, including a pair of second portions, the second portions are each being the second portion, in which the pair of second portions is located so as to sandwich the first portion in a direction intersecting the thickness direction of the substrate”. In this case, the boundary portion of the light absorbing layer with the second portion as viewed in the thickness direction of the substrate (outer edge of the light absorbing layer) can be more reliably heated from both sides of the light absorbing layer, and surface roughness of the light absorbing layer can be further prevented.

The light detection element according to an aspect of the present disclosure may be [7] “the light detection element according to any one of [1] to [6] described above, including a plurality of light absorbing layers, the light absorbing layers are each being the light absorbing layer, in which the plurality of light absorbing layers is arranged apart from each other in a direction intersecting the thickness direction of the substrate”. In this case, since the light detection element includes the plurality of light absorbing layers, the detection performance can be further improved.

A method for manufacturing a light detection element according to an aspect of the present disclosure is [8] “a method for manufacturing a light detection element including a step of preparing a substrate having a main surface; a step of forming an underlayer having a single crystal structure with a simple first material containing a first element on the main surface; a step of forming a light absorbing layer in an amorphous state on the underlayer with a second material that is a compound of the first element and a second element different from the first element; and a step of forming a light absorbing layer having a single crystal structure by heating the light absorbing layer in the amorphous state, in which, in the step of forming the light absorbing layer having the single crystal structure, the underlayer includes a first portion located between the substrate and the light absorbing layer in the amorphous state, and a second portion located outside the light absorbing layer in the amorphous state and adjacent to the first portion when viewed in a thickness direction of the substrate, the light absorbing layer is in contact with a first surface of the first portion on a side opposite to the substrate, and the light absorbing layer in the amorphous state is heated in a state in which, in the thickness direction of the substrate, a height from the main surface to a second surface of the second portion opposite to the substrate is equal to or greater than a height from the main surface to the first surface.

In the method for manufacturing the light detection element, for example, when the light absorbing layer in the amorphous state is single-crystallized by heating through light irradiation, the second portion absorbs light to generate heat. Due to the generated heat, a boundary portion of the light absorbing layer with the second portion when viewed in the thickness direction of the substrate (outer edge of the light absorbing layer) reaches the eutectic temperature earlier than the other portions. Accordingly, a single crystal nucleus is formed at the boundary portion, and single crystallization proceeds from the nucleus as a starting point toward the central portion of the light absorbing layer (from the outer edge toward the central portion of the light absorbing layer). This can prevent surface roughness of the light absorbing layer. Further, in the thickness direction of the substrate, a height from the main surface of the substrate to the second surface of the second portion is equal to or greater than a height from the main surface of the substrate to the first surface of the first portion. This facilitates the transfer of the heat generated in the second portion to the boundary portion of the light absorbing layer with the second portion. Therefore, a single crystal nucleus is easily formed at the boundary portion. Thus, according to the method for manufacturing a light detection element, surface roughness of the light absorbing layer is prevented, and the detection performance of the light detection element can be improved.

According to one aspect of the present disclosure, it is possible to provide a light detection element capable of improving detection performance, and a method for manufacturing such a light detection element.

### BRIEF DESCRIPTION OF THE DRAWINGS

FIG. 1 is a schematic cross-sectional view illustrating a light detection element according to a first embodiment;

FIG. 2 is a plan view illustrating the light detection element according to the first embodiment;

FIGS. 3A and 3B are diagrams each illustrating a method for manufacturing the light detection element according to the first embodiment;

FIGS. 4A and 4B are diagrams each illustrating a method for manufacturing the light detection element according to the first embodiment;

FIGS. 5A and 5B are diagrams each illustrating a method for manufacturing the light detection element according to the first embodiment;

FIGS. 6A and 6B are diagrams each illustrating a principle by which surface roughness of a light absorbing layer is prevented;

FIGS. 7A and 7B are diagrams each illustrating a principle by which surface roughness of a light absorbing layer is prevented;

FIG. 8 is a photograph showing a surface state of a light absorbing layer;

FIG. 9 is a photograph showing a surface state of a light absorbing layer;

FIG. 10 is a photograph showing a surface state of a light absorbing layer;

FIG. 11 is a schematic cross-sectional view illustrating a light detection element according to a second embodiment;

FIGS. 12A and 12B are diagrams each illustrating a method for manufacturing the light detection element according to the second embodiment;

FIGS. 13A and 13B are diagrams each illustrating a method for manufacturing the light detection element according to the second embodiment;

FIG. 14 is a schematic cross-sectional view illustrating a light detection element according to a third embodiment;

FIGS. 15A and 15B are diagrams each illustrating a method for manufacturing the light detection element according to the third embodiment;

FIGS. 16A and 16B are diagrams each illustrating a method for manufacturing the light detection element according to the third embodiment;

FIGS. 17A and 17B are diagrams each illustrating a method for manufacturing a light detection element according to a modification;

FIGS. 18A and 18B are diagrams each illustrating a method for manufacturing the light detection element according to the modification;

FIGS. 19A and 19B are diagrams each illustrating a method for manufacturing the light detection element according to the modification;

FIGS. 20A and 20B are diagrams each illustrating a method for manufacturing the light detection element according to the modification;

FIGS. 21A and 21B are diagrams each illustrating a method for manufacturing the light detection element according to the modification; and

FIGS. 22A and 22B are diagrams each illustrating a method for manufacturing the light detection element according to the modification.

### DETAILED DESCRIPTION

Hereinafter, an example of the present disclosure will be described in detail with reference to the drawings. Note that, in the drawings, the same or corresponding parts are denoted by the same reference signs, and redundant description will be omitted.

### First Embodiment

### [Configuration of Light Detection Element]

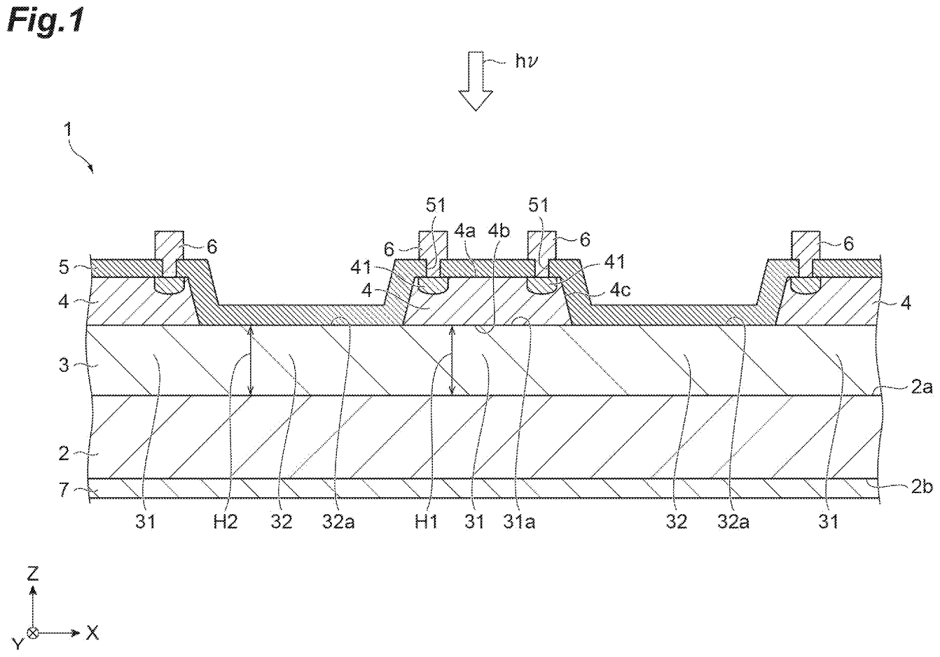

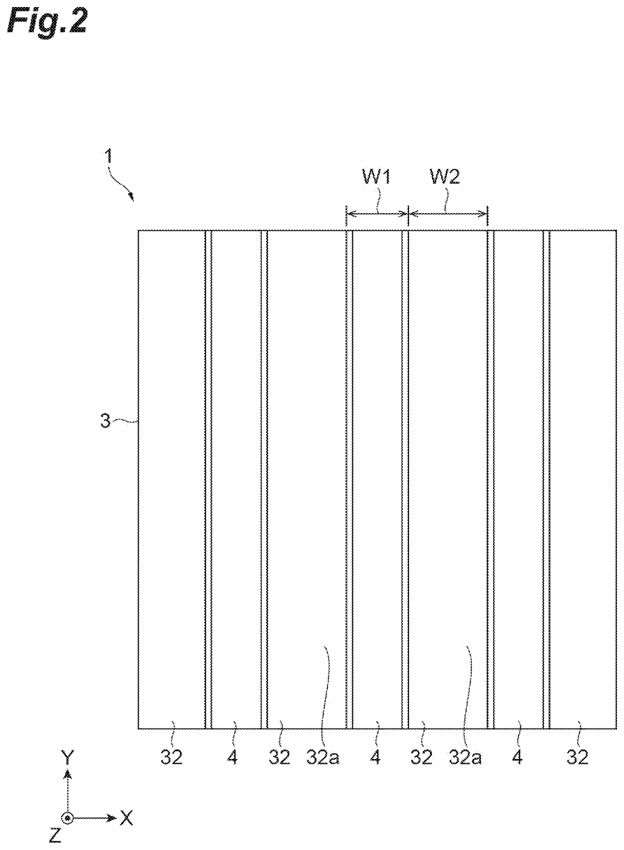

The configuration of a light detection element 1 according to the first embodiment will be described with reference to FIGS. 1 and 2. The light detection element 1 is an element for detecting light hν in a predetermined wavelength region. Hereinafter, a direction of incidence of the light hν with respect to the light detection element 1 is referred to as a Z-axis direction, one direction intersecting the Z-axis direction is referred to as an X-axis direction, and a direction intersecting both the Z-axis direction and the X-axis direction is referred to as a Y-axis direction. The X-axis direction, the Y-axis direction, and the Z-axis direction are orthogonal to each other. The light detection element 1 may be, for example, a SWIR light receiving element that detects light in a short wave infrared region (wavelength region of 1.0 μm or more and 3.0 μm or less, for example). The light detection element 1 includes a substrate 2, an underlayer 3, a plurality of light absorbing layers 4, a passivation layer 5, a plurality of anode electrodes 6, and a cathode electrode 7. In FIG. 2, illustrations of the passivation layer 5 and the anode electrodes 6 are omitted.

The substrate 2 is a semiconductor substrate. In the present embodiment, the substrate 2 is formed of silicon doped with impurities. The substrate 2 has a first conductivity type (n-type in this example). The thickness direction of the substrate 2 is along the Z-axis direction. The substrate 2 is formed in a rectangular plate shape. The shape of the substrate 2 is not limited. The substrate 2 has a main surface 2a and a main surface 2b. The main surface 2b is located on the side opposite to the main surface 2a.

The underlayer 3 is a semiconductor layer formed on the main surface 2a of the substrate 2. The thickness of the underlayer 3 is, for example, about 500 nm. The underlayer 3 is directly formed on the main surface 2a. The underlayer 3 is in contact with the main surface 2a. The underlayer 3 is formed of a semiconductor material that is not doped with impurities. The underlayer 3 is formed of a simple first material containing a first element. The simple first material containing the first element is a material containing one type of the first element in a state of not being combined with a different element. In this example, the first element is a group 14 element. More specifically, the first element is Ge. The underlayer 3 has a single crystal structure. The single crystal structure is a crystal structure in which atoms or molecules are regularly arranged in three dimensions.

The underlayer 3 includes a plurality of first portions 31 and a plurality of second portions 32. Each of the first portions 31 is located between the substrate 2 and the corresponding light absorbing layer 4 among the plurality of light absorbing layers 4 to be described later. The first portions 31 overlap the light absorbing layers 4 when viewed in the Z-axis direction. Each of the second portions 32 is located outside the corresponding light absorbing layer 4 when viewed in the Z-axis direction. The second portions 32 do not overlap the light absorbing layers 4 when viewed in the Z-axis direction. The plurality of first portions 31 and the plurality of second portions 32 are alternately arranged in the X-axis direction. That is, a pair of adjacent second portions 32 is located so as to sandwich one corresponding first portion 31 in the X-axis direction. Each of the second portions 32 is adjacent to the corresponding first portion 31 in the X-axis direction. Each of the second portions 32 is continuous with the corresponding first portion 31 in the X-axis direction.

Each of the first portions 31 has a surface (first surface) 31a opposite to the substrate 2. Each of the second portions 32 has a surface (second surface) 32a opposite to the substrate 2. In this example, the surfaces 31a and the surfaces 32a extend perpendicular to the Z-axis direction. In the Z-axis direction, a height (maximum height) H2 from the main surface 2a of the substrate 2 to the surface 32a is equal to or greater than a height (maximum height) H1 from the main surface 2a to the surface 31a. In this example, the height H2 is equal to the height H1. A thickness (maximum thickness) of the second portion 32 is equal to or larger than a thickness (maximum thickness) of the first portion 31. In this example, the thickness of the second portion 32 is equal to the thickness of the first portion 31.

The light absorbing layers 4 are semiconductor layers formed on the underlayer 3. A thickness of each of the light absorbing layers 4 is, for example, about 100 nm. Each of the light absorbing layers 4 is directly formed on the corresponding first portion 31 of the plurality of first portions 31. Each of the light absorbing layers 4 is in contact with the surface 31a of the corresponding first portion 31. The light absorbing layers 4 are formed of a second material that is a compound of the first element and a second element different from the first element. That is, the second material is a compound formed by the combination of two elements different from each other. The first element contained in the second material is the same as the first element contained in the first material. As described above, the first element is a group 14 element in this example. More specifically, the first element is Ge. The second element is a group 14 element different from the first element. More specifically, the second element is Sn. The light absorbing layers 4 each have a single crystal structure.

In the X-axis direction, the plurality of light absorbing layers 4 is arranged apart from each other. That is, the plurality of light absorbing layers 4 is not continuous with each other in the X-axis direction. Each of the light absorbing layers 4 has a surface 4a on the side opposite to the substrate 2, a surface 4b on the substrate 2 side, and a side surface 4c connecting the surface 4a and the surface 4b. The surface 4b is in contact with the surface 31a of the first portion 31. Each of the light absorbing layers 4 has a mesa structure. More specifically, the light absorbing layer 4 is formed in a trapezoidal shape in a cross section (FIG. 1) perpendicular to the Y-axis direction. The width of the light absorbing layer 4 in the X-axis direction decreases from the surface 4b toward the surface 4a. When viewed in the Z-axis direction (FIG. 2), the light absorbing layers 4 extend along the Y-axis direction. When viewed in the Z-axis direction, the light absorbing layers 4 each have a rectangular shape having a long side along the Y-axis direction.

In this example, a width W1 (maximum width) of the light absorbing layer 4 in the X-axis direction is 0.05 mm or more and 4 mm or less. The width W1 may be 2 mm or less, 1 mm or less, 0.5 mm or less, 0.2 mm or less, or 0.05 mm or less. An interval W2 (maximum interval) between the light absorbing layers 4 in the X-axis direction may be, for example, about 0.1 mm. Since a gap is formed between the light absorbing layers 4, each second portion 32 of the underlayer 3 is exposed from the gap between the corresponding pair of light absorbing layers 4.

Each of the light absorbing layers 4 has a plurality of contact regions 41. The contact region 41 is a region doped with impurities. The contact region 41 has a second conductivity type (p-type in this example). The contact region 41 may be formed by using, for example, an ion implantation process. The contact region 41 is exposed to the outside of the light absorbing layer 4 on the surface 4a of the light absorbing layer 4.

The passivation layer 5 is formed on the underlayer 3 and the light absorbing layer 4. The passivation layer 5 is continuously formed on the surface 32a of the second portion 32, and the surface 4a as well as the side surface 4c of the light absorbing layer 4. A plurality of through holes 51 is formed in a part of the passivation layer 5 overlapping the contact region 41. The contact region 41 is exposed from each of the through holes 51.

The plurality of anode electrodes 6 is formed on the light absorbing layer 4. Each of the anode electrodes 6 is in contact with the contact region 41 of the light absorbing layer 4 via the through hole 51. The anode electrode 6 is made of metal. The cathode electrode 7 is formed on the substrate 2. The cathode electrode 7 is in contact with the main surface 2b of the substrate 2. The cathode electrode 7 is made of metal.

### [Operation of Light Detection Element]

The operation of the light detection element 1 will be described. First, light hv to be detected enters the light detection element 1. The light hv passes through the passivation layer 5 to enter the light absorbing layer 4. The incident light hv generates charge carriers (holes and electrons) in the light absorbing layer 4. The generated charge carriers are output, as current signals, to the outside via the anode electrodes 6 and the cathode electrode 7. Specifically, the generated holes move to the contact regions 41 and are extracted to the outside via the anode electrodes 6 connected to the contact regions 41. On the other hand, the generated electrons move to the substrate 2 and are extracted to the outside via the cathode electrode 7 connected to the substrate 2.

### [Method for Manufacturing Light Detection Element]

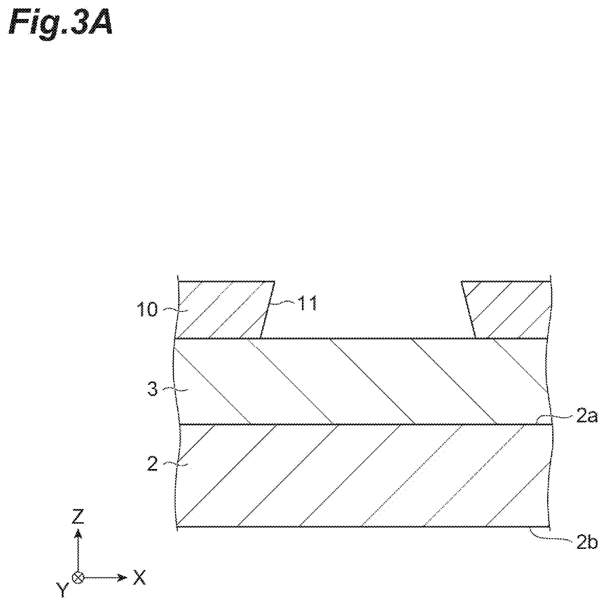

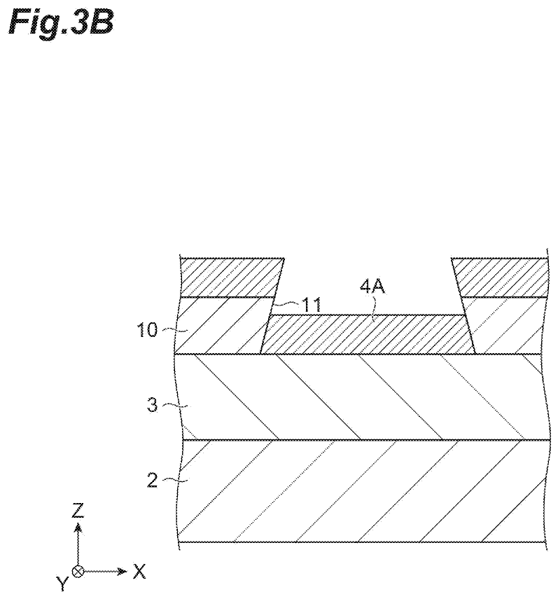

A method for manufacturing the light detection element 1 will be described with reference to FIGS. 3A, 3B, 4A, 4B, 5A, and 5B. First, as illustrated in FIG. 3A, the substrate 2 is prepared. Next, on the main surface 2a of the substrate 2, the underlayer 3 having a single crystal structure is formed with the simple first material containing the first element. In this example, the underlayer 3 is formed of Ge. The underlayer 3 may be formed by a molecular beam epitaxy (MBE) method, a chemical vapor deposition (CVD) method, or a sputtering method.

Subsequently, a light absorbing layer 4A (FIG. 3B) in an amorphous state is formed on the underlayer 3 with the second material that is a compound of the first element and the second element different from the first element. The amorphous state is a state in which atoms or molecules are irregularly (randomly) arranged in three dimensions. As illustrated in FIG. 3A, a resist 10 (a photoresist in this example) is uniformly applied onto the underlayer 3. The resist 10 may be applied by using a method such as spin coating. Next, a photomask is used to perform exposure and development to form a plurality of openings 11 (patterns) in the resist 10. Although only one opening 11 formed in the resist 10 is illustrated in FIGS. 3A and 3B for convenience of description, the number of openings 11 formed may be the same as the number of light absorbing layers 4 included in the light detection element 1. The opening 11 is formed at a position corresponding to a region where the light absorbing layer 4 is to be formed in a later step.

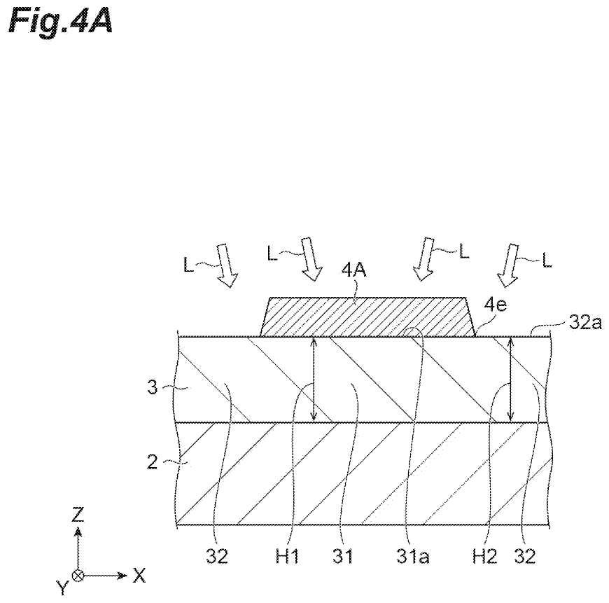

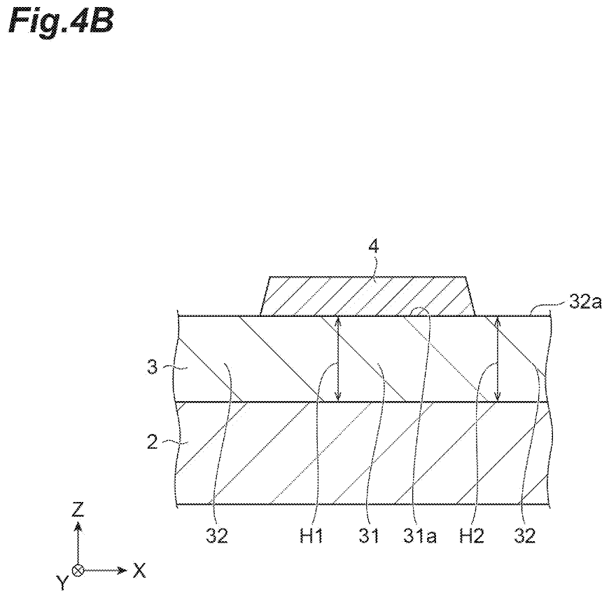

Subsequently, as illustrated in FIG. 3B, the plurality of light absorbing layers 4A in the amorphous state is formed, with the second material, on the underlayer 3 on which the resist 10 is formed. In this example, the light absorbing layer 4A is formed by using a sputtering method. At this time, the light absorbing layer 4A is formed not only on the surface of the underlayer 3 exposed from the opening 11 but also on the resist 10. Next, as illustrated in FIG. 4A, the resist 10 is removed (lifted off) together with the light absorbing layer 4A formed on the resist 10. As a result, the light absorbing layer 4A in the amorphous state having a desired shape is formed on the underlayer 3.

The light absorbing layer 4A in the amorphous state is a layer that becomes the light absorbing layer 4 having a single crystal structure through a later step. Therefore, a part of the underlayer 3 located between the substrate 2 and the light absorbing layer 4A corresponds to the first portion 31, and a part of the underlayer 3 located outside the light absorbing layer 4A and adjacent to the first portion 31 when viewed in the Z-axis direction corresponds to the second portion 32. The light absorbing layer 4A is in contact with the surface 31a of the first portion 31. In the Z-axis direction, the height H2 from the main surface 2a of the substrate 2 to the surface 32a of the second portion 32 is equal to or greater than the height H1 from the main surface 2a to the surface 31a of the first portion 31. In this example, the height H2 is equal to the height H1. In this state, the light absorbing layer 4A in the amorphous state is heated to form the light absorbing layer 4 having a single crystal structure (FIG. 4B). The light absorbing layer 4A is single-crystallized by using a solid phase growth method (SPC). In the present embodiment, the light absorbing layer 4A is heated by rapid thermal annealing (RTA) using light irradiation. As illustrated in FIG. 4A, the light absorbing layer 4A and the underlayer 3 are irradiated with light L, and the light absorbing layer 4A and the underlayer 3 generate heat. In this example, the light absorbing layer 4A is heated to 600 °C or higher. At this time, a susceptor may be disposed so as to face the main surface 2b of the substrate 2, and heating may be performed also from the substrate 2 side using the susceptor.

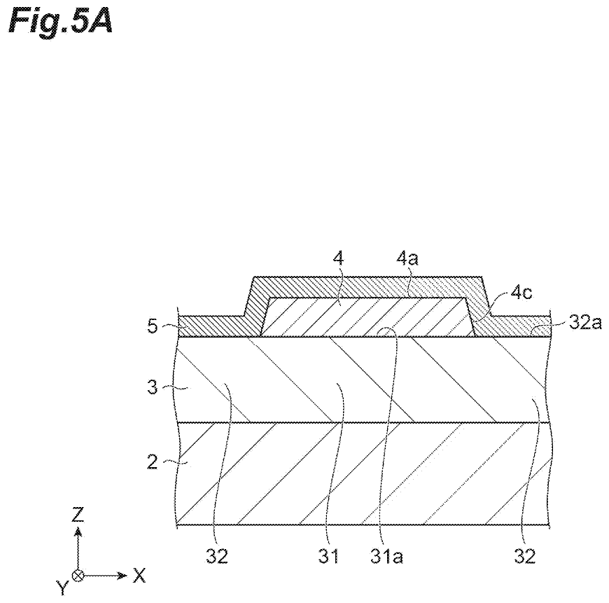

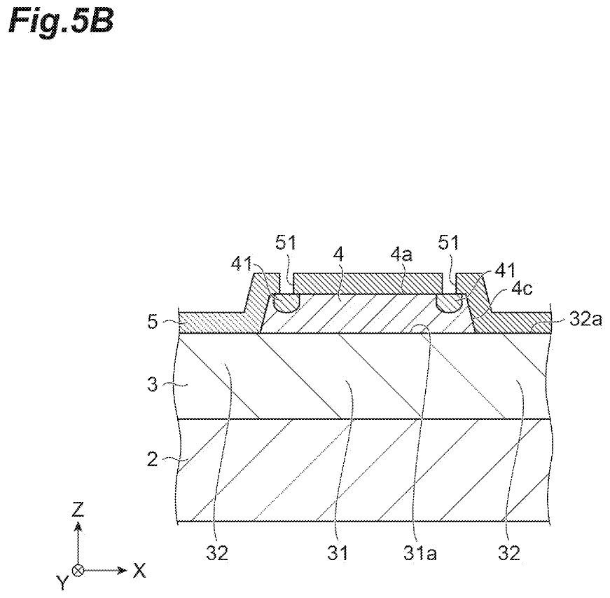

Subsequently, as illustrated in FIG. 5A, the passivation layer 5 is formed on the underlayer 3 and the light absorbing layer 4. The passivation layer 5 is continuously formed on the surface 32a of the second portion 32, and the surface 4a as well as the side surface 4c of the light absorbing layer 4.

Next, as illustrated in FIG. 5B, the plurality of through holes 51 is formed in the passivation layer 5. The surface 4a of the light absorbing layer 4 is exposed from the through holes 51. Then, the plurality of contact regions 41 is formed in the light absorbing layer 4. In this example, the contact regions 41 are formed by using an ion implantation process through the through holes 51.

Next, as illustrated in FIG. 1, the plurality of anode electrodes 6 is formed on the light absorbing layer 4. Each of the anode electrodes 6 is formed so as to be in contact with the contact region 41 of the light absorbing layer 4 via the through hole 51. Then, the cathode electrode 7 is formed on the substrate 2. The cathode electrode 7 is formed so as to be in contact with the main surface 2b of the substrate 2. Through the above manufacturing process, the light detection element 1 is manufactured.

### [Operations and Effects]

In the light detection element 1, the underlayer 3 includes the first portion 31 located between the substrate 2 and the light absorbing layer 4 and the second portion 32 located outside the light absorbing layer 4 and adjacent to the first portion 31 when viewed in the Z-axis direction. That is, the second portion 32 of the underlayer 3 is formed outside the light absorbing layer 4 when viewed in the Z-axis direction. In this case, in the process of manufacturing the light detection element 1, for example, when the light absorbing layer 4A in the amorphous state is single-crystallized by heating through light irradiation, the second portion 32 absorbs light to generate heat. Due to the generated heat, a boundary portion 4e of the light absorbing layer 4A with the second portion 32 when viewed in the Z-axis direction (outer edge of the light absorbing layer 4) reaches the eutectic temperature earlier than the other portions (FIG. 4A). Accordingly, a single crystal nucleus is formed at the boundary portion 4e, and single crystallization proceeds from the nucleus as a starting point toward the central portion of the light absorbing layer 4 (from the outer edge toward the central portion of the light absorbing layer 4). As a result, surface roughness (irregularity structure occurring on the surface 4a) of the light absorbing layer 4 can be prevented. Further, in the Z-axis direction, the height H2 from the main surface 2a of the substrate to the surface 32a of the second portion 32 is equal to or greater than the height H1 from the main surface 2a of the substrate to the surface 31a of the first portion 31. This facilitates the transfer of the heat generated in the second portion 32 to the boundary portion 4e of the light absorbing layer 4A with the second portion 32. Therefore, a single crystal nucleus is easily formed at the boundary portion 4e. Thus, according to the light detection element 1, surface roughness of the light absorbing layer 4 is prevented, and the detection performance can be improved.

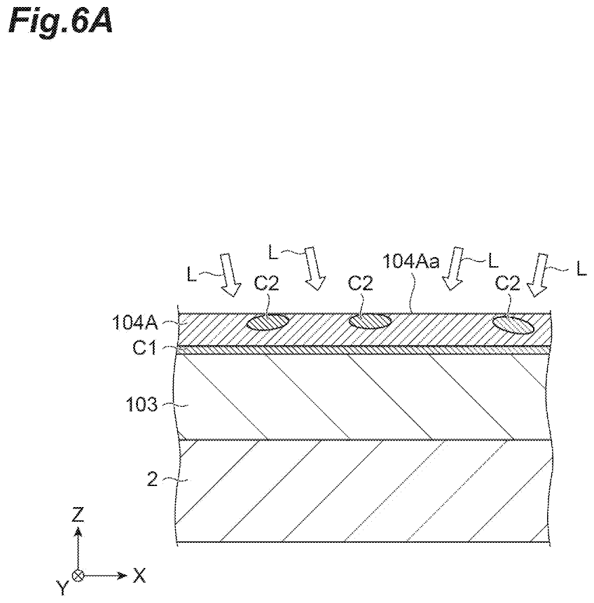

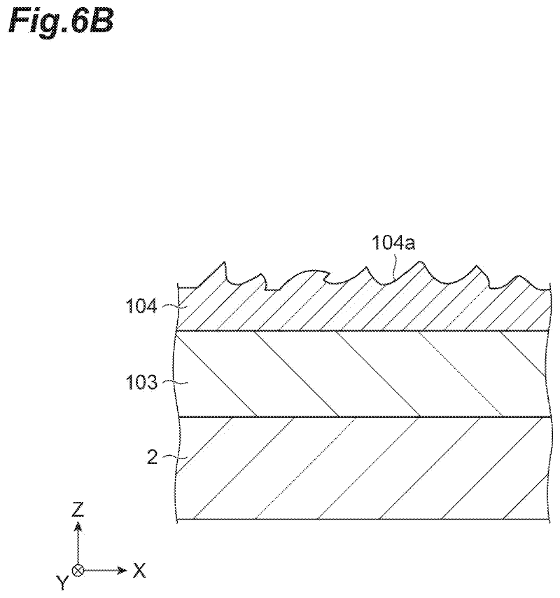

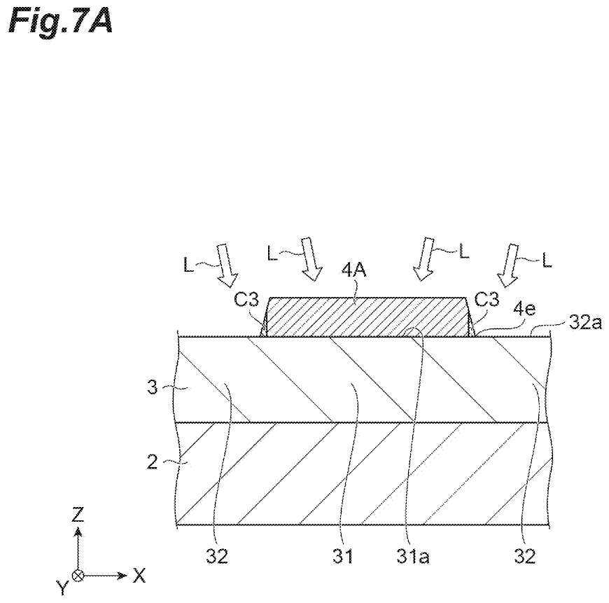

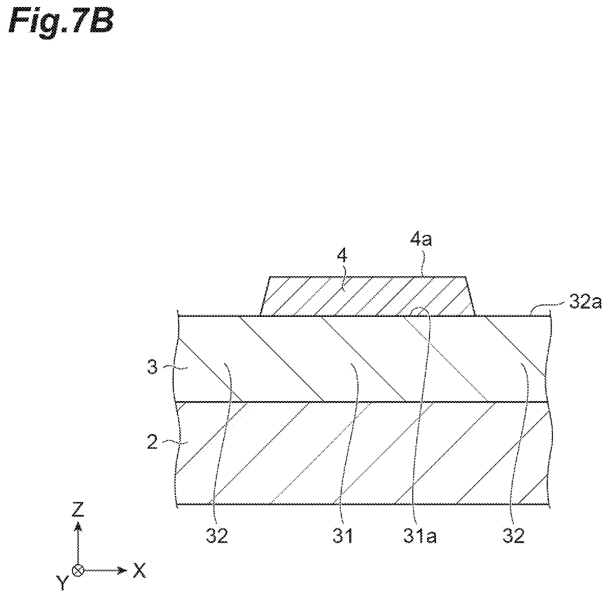

The principle by which surface roughness of the light absorbing layer 4 is prevented will be described more specifically with reference to FIGS. 6A, 6B, 7A, and 7B. FIGS. 6A and 6B are cross-sectional views each illustrating a process of manufacturing a light detection element according to a first comparative example, and FIGS. 7A and 7B are cross-sectional views each illustrating a process of manufacturing the light detection element 1 according to the present embodiment. As illustrated in FIG. 6A, in the configuration of the first comparative example, a light absorbing layer 104A in an amorphous state is formed over the entire underlayer 103 (the underlayer 103 does not have a part corresponding to the second portion 32). When the configuration of the first comparative example is irradiated with light L, a single crystal nucleus C1 is formed at the interface between the underlayer 3 and the light absorbing layer 104A, and a polycrystalline nucleus C2 is formed on a surface 104Aa of the light absorbing layer 104A opposite to the substrate 2. Then, crystallization proceeds from each of the nuclei C1 and C2 as a starting point. The crystallization proceeds along the Z-axis direction. When the crystallization proceeds, a part crystallized from the nucleus C1 as a starting point and a part crystallized from the nucleus C2 as a starting point collide with each other, and surface roughness occurs as illustrated in FIG. 6B. Specifically, in the light absorbing layer 104 having a single crystal structure, surface roughness occurs on a surface 104a (plane of light incidence) opposite to the substrate 2.

On the other hand, when the configuration of the present embodiment as illustrated in FIG. 7A is irradiated with light L, the second portion 32 absorbs the light to generate heat. Due to the generated heat, a boundary portion 4e of the light absorbing layer 4A with the second portion 32 when viewed in the Z-axis direction (outer edge of the light absorbing layer 4) reaches the eutectic temperature earlier than the other portions. Therefore, a single crystal nucleus C3 is formed in the boundary portion 4e, and lateral single crystallization (lateral crystallization) proceeds from the nucleus C3 as a starting point toward the central portion of the light absorbing layer 4. The single crystallization proceeds along the X-axis direction. As a result, surface roughness on the surface 4a of the light absorbing layer 4 having a single crystal structure is suppressed.

The light detection elements according to first to fifth examples and the first comparative example were manufactured, and the surface state of the light absorbing layers was confirmed. The light detection element of the first example was a light detection element including one rectangular light absorbing layer having a width of 4 mm×2 mm when viewed in the thickness direction of the substrate. In the first example, when viewed in the thickness direction of the substrate, there is a part of the underlayer not overlapping the light absorbing layer outside the light absorbing layer. Each of the light detection elements according to the second to fifth examples is a light detection element including a plurality of light absorbing layers, similarly to the light detection element 1 according to the first embodiment. In the light detection element according to the second example, the width (corresponding to the width W1 in FIG. 2) of each light absorbing layer along the X-axis direction was 1 mm. In the light detection element according to the third example, the width of each light absorbing layer along the X-axis direction was 0.5 mm. In the light detection element according to the fourth example, the width of each light absorbing layer along the X-axis direction was 0.2 mm. In the light detection element according to the fifth example, the width of each light absorbing layer along the X-axis direction was 0.05 mm. In each of the light detection elements according to the second to fifth examples, the interval between the light absorbing layers (corresponding to the interval W2 in FIG. 2) was 0.1 mm. In each of the light detection elements according to the second to fifth examples, an interval (gap) is formed between the light absorbing layers, and thus, when viewed in the thickness direction of the substrate, there is a part of the underlayer not overlapping the light absorbing layer outside the light absorbing layer. Therefore, the light detection elements according to the first to fifth examples each include a part corresponding to the second portion 32 of the underlayer 3 of the above embodiment.

In contrast, the light detection element according to the first comparative example was a light detection element in which the light absorbing layer overlaps the entire underlayer when viewed in the thickness direction of the substrate. That is, the light detection element according to the first comparative example does not have a part corresponding to the second portion 32 of the underlayer 3 in the above embodiment. The light absorbing layer in the amorphous state was heated to form a light absorbing layer having a single crystal structure, and then the light detection elements according to the examples and the comparative example were manufactured, and surface roughness of the light absorbing layer was confirmed.

In the light detection elements according to the first to fifth examples, the surface of the light absorbing layer was smooth, whereas in the first comparative example, the surface was extremely rough. Therefore, it was confirmed that the surface roughness of the light absorbing layer was prevented by providing a part of the underlayer not overlapping the light absorbing layer outside the light absorbing layer (by forming the light absorbing layer in a pattern) when viewed in the thickness direction of the substrate without covering the entire underlayer with the light absorbing layer.

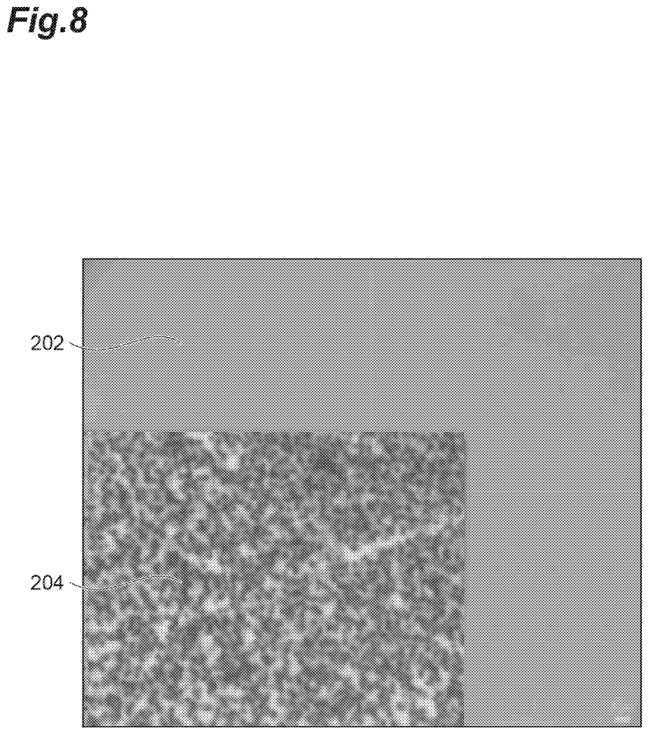

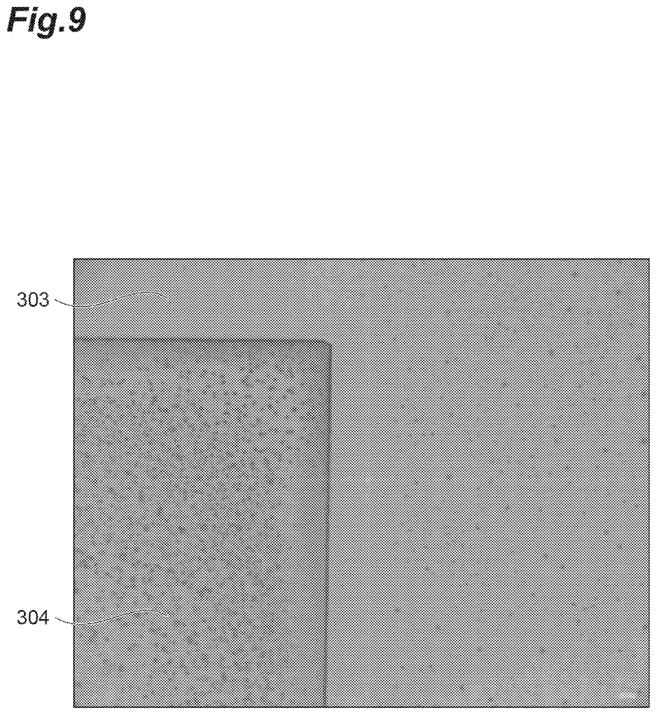

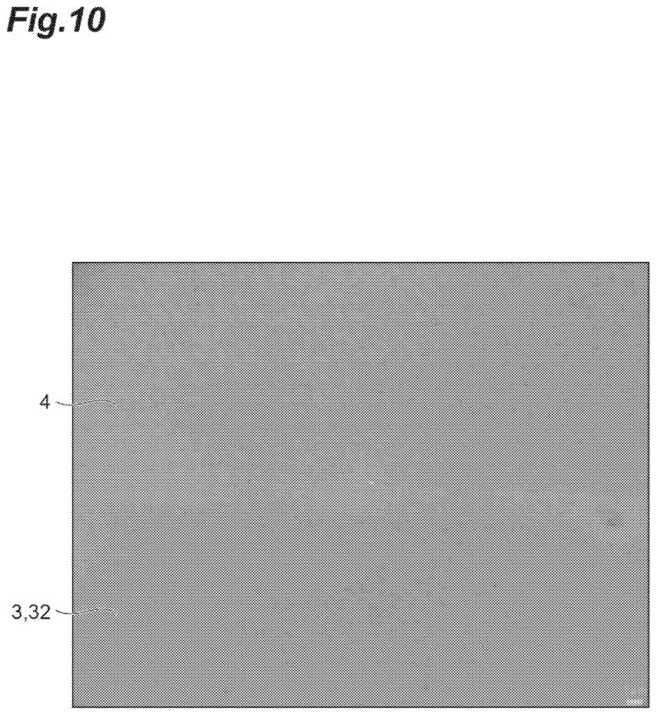

Next, the influence of the relationship between the height H1 of the first portion 31 and the height H2 of the second portion 32 on the surface state of the light absorbing layer 4 will be described. FIG. 8 is a photograph showing a surface state of a light absorbing layer of a light detection element according to a second comparative example. FIG. 9 is a photograph showing a surface state of a light absorbing layer of a light detection element according to a third comparative example. FIG. 10 is a photograph showing a surface state of a light absorbing layer of a light detection element according to a sixth example. In the second comparative example, in the process of manufacturing the light detection element, a part of the underlayer 3 corresponding to the second portion 32 is removed by etching, and the substrate (part indicated by reference numeral 202 in FIG. 8) is exposed. In this state, the light absorbing layer in the amorphous state was heated to form a light absorbing layer having a single crystal structure (part indicated by reference numeral 204 in FIG. 8). In the photograph shown in FIG. 8, it can be seen that there is significant variation in color intensity (color unevenness) on the surface of the light absorbing layer, and the surface is extremely rough.

In the third comparative example, in the process of manufacturing the light detection element, an upper part of the underlayer 3 corresponding to the second portion 32 (part indicated by reference numeral 303 in FIG. 9) was removed by etching so that a height (height H2 in FIG. 1) of a part corresponding to the surface 32a of the second portion 32 was lower, by 100 nm, than a height (height H1 in FIG. 1) of a part corresponding to the surface 31a of the first portion 31. In this state, the light absorbing layer in the amorphous state was heated to form a light absorbing layer having a single crystal structure (part indicated by reference numeral 304 in FIG. 9). In the photograph shown in FIG. 9, it can be seen that the variation in color intensity is smaller than that in the photograph of FIG. 8 (second comparative example), but the surface is rough.

The method for manufacturing the light detection element according to the sixth example is similar to that of the light detection element 1 according to the first embodiment. That is, in the process of manufacturing the light detection element, in a state where the height H2 of the surface 32a of the second portion 32 is equal to the height H1 of the surface 31a of the first portion 31, the light absorbing layer 4A in the amorphous state is heated to form the light absorbing layer 4 having a single crystal structure. In the photograph shown in FIG. 10, it was confirmed that the variation in color intensity on the surface of the light absorbing layer 4 was extremely reduced, and the surface roughness was reduced.

The first element is a group 14 element, and the second element is a group 14 element different from the first element. Since both the first element and the second element are group 14 elements, the band energy of the light absorbing layer 4 formed of the second material which is a compound of the first element and the second element can be controlled, so that light having a desired wavelength can be absorbed by the light absorbing layer 4. Lattice matching of the light absorbing layer 4 formed of the second material which is a compound of the first element and the second element is improved, thereby preventing the occurrence of crystal defects.

The first element is Ge, and the second element is Sn. Thus, the light absorbing layer 4 can function as a layer that absorbs light in a short wave infrared (SWIR) region.

In the X-axis direction, the pair of second portions 32 is located so as to sandwich the first portion 31 therebetween. Thus, the boundary portion 4e of the light absorbing layer 4 with the second portion 32 as viewed in the Z-axis direction can be more reliably heated from both sides of the light absorbing layer 4 in the X-axis direction, and surface roughness of the light absorbing layer 4 can be further prevented.

The light detection element 1 includes the plurality of light absorbing layers 4, and the plurality of light absorbing layers 4 is arranged apart from each other in the X-axis direction. Since the light detection element 1 includes the plurality of light absorbing layers 4, the detection performance can be further improved.

According to the method for manufacturing the light detection element 1, surface roughness of the light absorbing layer 4 is prevented, and the detection performance of the light detection element 1 can be improved for a reason similar to that described above.

### Second Embodiment

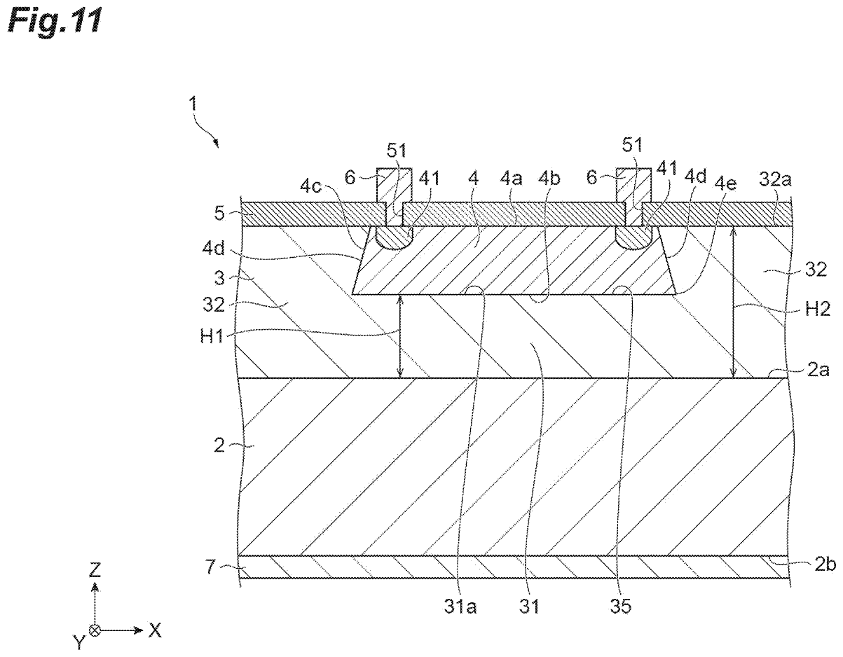

A light detection element 1 and a method for manufacturing the light detection element 1 according to the second embodiment will be described. Hereinafter, differences from the first embodiment will be mainly described, and description of common points may be omitted. FIG. 11 is a schematic cross-sectional view illustrating the light detection element 1 according to the second embodiment. As illustrated in FIG. 11, the light detection element 1 according to the second embodiment is different from the light detection element 1 according to the first embodiment in the configuration of an underlayer 3. More specifically, the underlayer 3 is formed with a plurality of recesses 35, and each of a plurality of light absorbing layers 4 is disposed inside the corresponding recess 35. The recesses 35 are recessed from the surface of the underlayer 3 opposite to a substrate 2 toward the substrate 2. The bottom surface of the recess 35 is constituted by a surface 31a of a first portion 31.

In the present embodiment, the entire light absorbing layer 4 is disposed inside the recess 35. In the Z-axis direction, a height H2 from a main surface 2a of the substrate 2 to a surface 32a of a second portion 32 is greater than a height H1 from the main surface 2a to the surface 31a of the first portion 31. A thickness of the second portion 32 is larger than a thickness of the first portion 31. In the Z-axis direction, the height H2 coincides with a height from the main surface 2a to a surface 4a of the light absorbing layer 4. The second portion 32 is in contact with a side surface 4c of the light absorbing layer 4. A pair of corresponding second portions 32 in the X-axis direction is located so as to sandwich the light absorbing layer 4 therebetween. The side surface 4c includes a pair of regions 4d facing each other in the X-axis direction. Each of the pair of second portions 32 is in contact with the entirety of the corresponding region 4d of the pair of regions 4d.

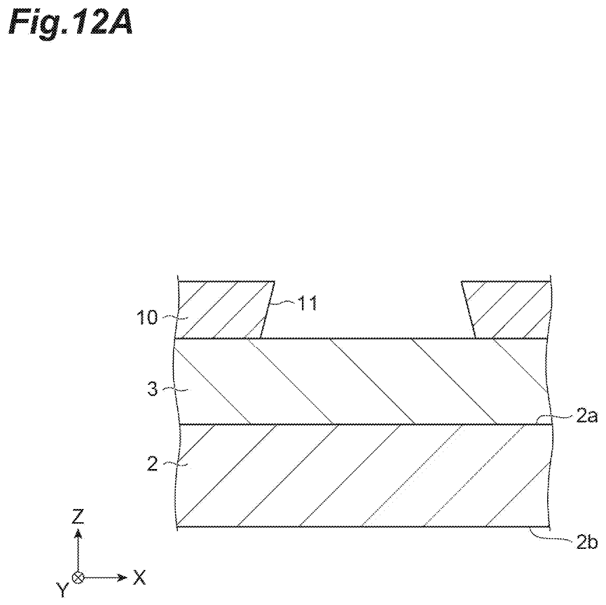

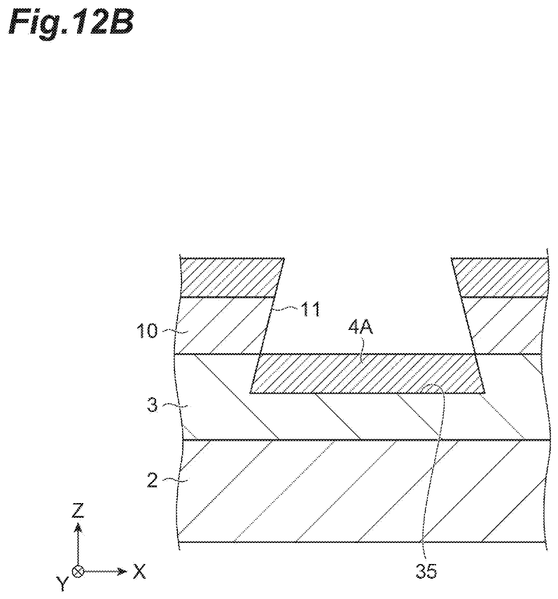

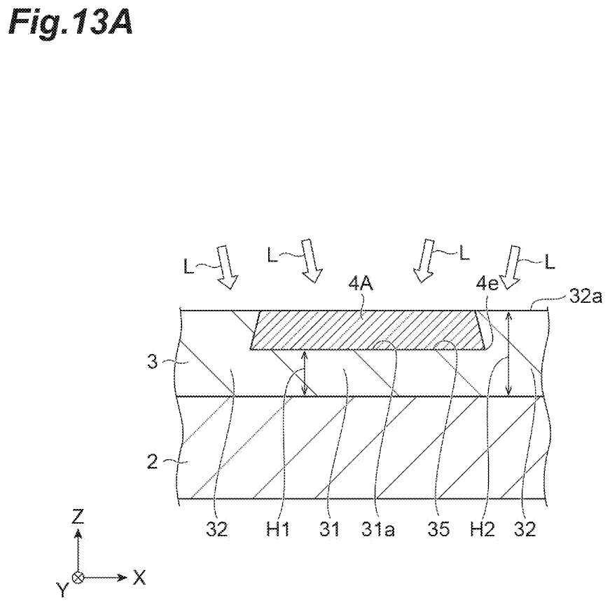

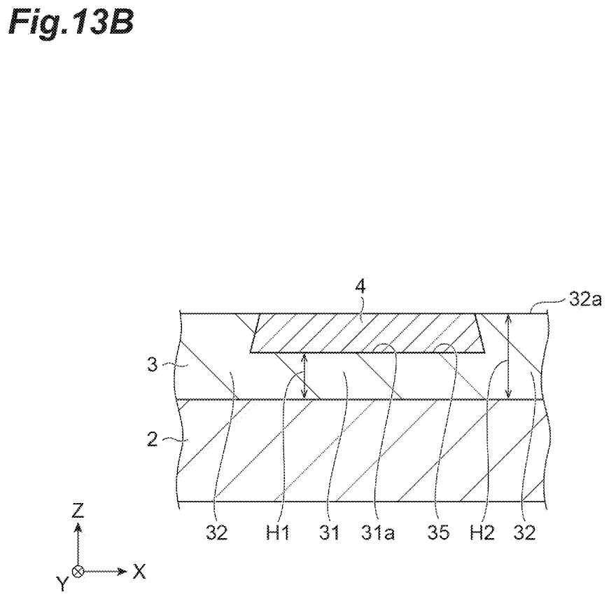

The method for manufacturing the light detection element 1 according to the second embodiment will be described with reference to FIGS. 12A, 12B, 13A, and 13B. First, as illustrated in FIG. 12A, the substrate 2 is prepared. Next, on the main surface 2a of the substrate 2, the underlayer 3 having a single crystal structure is formed with the simple first material containing the first element. In this example, the underlayer 3 is formed of Ge. The underlayer 3 may be formed by a molecular beam epitaxy (MBE) method, a chemical vapor deposition (CVD) method, or a sputtering method.

Subsequently, a light absorbing layer 4A (FIG. 12B) in an amorphous state is formed on the underlayer 3 with the second material that is a compound of the first element and the second element different from the first element. Specifically, first, as illustrated in FIG. 12A, a resist 10 having a plurality of openings 11 (patterns) is formed on the underlayer 3. A method for forming the resist 10 is similar to the method described in the first embodiment.

Next, as illustrated in FIG. 12B, a part of the underlayer 3 corresponding to the plurality of openings 11 of the resist 10 is removed by etching to form the plurality of recesses 35. Subsequently, the plurality of light absorbing layers 4A in the amorphous state is formed, with the second material, on the underlayer 3 on which the resist 10 is formed. In this example, the light absorbing layer 4A is formed by using a sputtering method. At this time, the light absorbing layer 4A is formed not only on the surface of the underlayer 3 exposed from the opening 11 but also on the resist 10. Then, as illustrated in FIG. 13A, the resist 10 is removed (lifted off) together with the light absorbing layer 4A formed on the resist 10, so that the light absorbing layer 4A in the amorphous state having a desired shape is formed on the underlayer 3.

The light absorbing layer 4A is in contact with the surface 31a of the first portion 31. In the Z-axis direction, the height H2 from the main surface 2a of the substrate 2 to the surface 32a of the second portion 32 is greater than a height H1 from the main surface 2a to the surface 31a of the first portion 31. In this state, the light absorbing layer 4A in the amorphous state is heated to form the light absorbing layer 4 having a single crystal structure (FIG. 13B). As in the first embodiment, the light absorbing layer 4A is heated by RTA using light irradiation. As illustrated in FIG. 13A, the light absorbing layer 4A and the underlayer 3 are irradiated with light L, and the light absorbing layer 4A and the underlayer 3 generate heat. In this example, the light absorbing layer 4A is heated to 600 °C or higher.

Subsequently, as illustrated in FIG. 11, a passivation layer 5, a contact region 41, an anode electrode 6, and a cathode electrode 7 are formed. The method for forming the passivation layer 5, the contact region 41, the anode electrode 6, and the cathode electrode 7 is similar to the method described in the first embodiment. Through the above manufacturing process, the light detection element 1 according to the second embodiment is manufactured.

The light detection element 1 according to the present embodiment can also prevent surface roughness of the light absorbing layer 4 and improve detection performance for a reason similar to that of the light detection element 1 according to the first embodiment.

In the present embodiment, in the Z-axis direction, the height H2 from the main surface 2a to the surface 32a is greater than the height H1 from the main surface 2a to the surface 31a. Thus, a boundary portion 4e (side surface 4c) of the light absorbing layer 4 with the second portion 32 as viewed in the Z-axis direction can be more reliably heated, and surface roughness of the light absorbing layer 4 can be further prevented.

In the present embodiment, the light absorbing layer 4 has the side surface 4c connecting the surface 4a of the light absorbing layer 4 and a surface 4b of the light absorbing layer 4, and the second portion 32 is in contact with the side surface 4c. Thus, a boundary portion 4e (side surface 4c) of the light absorbing layer 4 with the second portion 32 as viewed in the Z-axis direction can be more reliably heated, and surface roughness of the light absorbing layer 4 can be further prevented.

### Third Embodiment

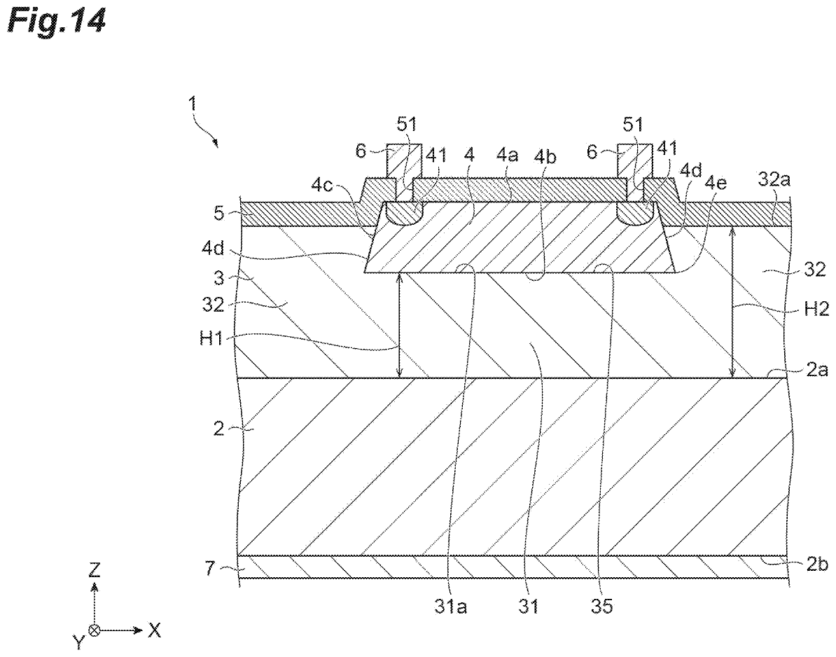

A light detection element 1 and a method for manufacturing the light detection element 1 according to the third embodiment will be described. Hereinafter, differences from the first embodiment will be mainly described, and description of common points may be omitted. FIG. 14 is a schematic cross-sectional view illustrating the light detection element 1 according to the third embodiment. As illustrated in FIG. 14, the light detection element 1 according to the third embodiment is different from the light detection element 1 according to the first embodiment in the configuration of an underlayer 3. More specifically, the underlayer 3 is formed with a plurality of recesses 35, and each of a plurality of light absorbing layers 4 is disposed inside the corresponding recess 35. The recesses 35 are recessed from the surface of the underlayer 3 opposite to a substrate 2 toward the substrate 2. The bottom surface of the recess 35 is constituted by a surface 31a of a first portion 31.

In the present embodiment, a part of the light absorbing layer 4 is disposed inside the recess 35. A part of the light absorbing layer 4 on a surface 4b side is disposed inside the recess 35, and a part of the light absorbing layer 4 on a surface 4a side is disposed outside the recess 35. The part of the light absorbing layer 4 on the surface 4a side may be a part having a thickness corresponding to 20% or more and 80% or less, or a part having a thickness corresponding to 40% or more and 60% or less of the entire thickness of the light absorbing layer 4 in the Z-axis direction. In the Z-axis direction, a height H2 from a main surface 2a of the substrate 2 to a surface 32a of a second portion 32 is greater than a height H1 from the main surface 2a to the surface 31a of the first portion 31. A thickness of the second portion 32 is larger than a thickness of the first portion 31. In the Z-axis direction, the height H2 is smaller than a height from the main surface 2a to the surface 4a of the light absorbing layer 4. The second portion 32 is in contact with a side surface 4c of the light absorbing layer 4. A pair of corresponding second portions 32 in the X-axis direction is located so as to sandwich the light absorbing layer 4 therebetween. The side surface 4c includes a pair of regions 4d facing each other in the X-axis direction. Each of the pair of second portions 32 is in contact with a part of the corresponding region 4d of the pair of regions 4d.

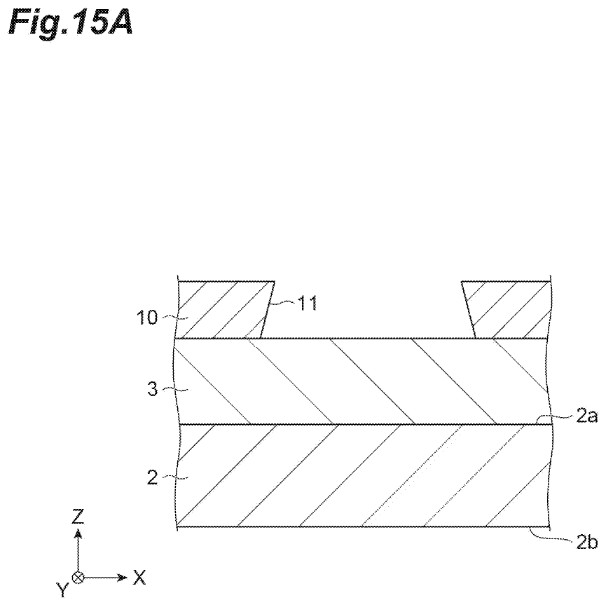

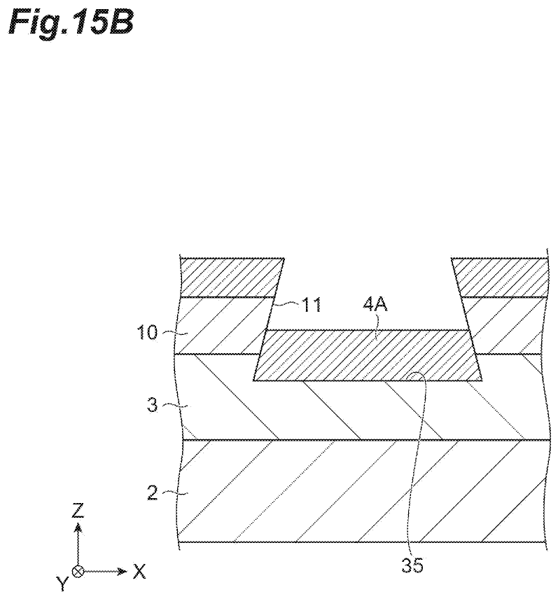

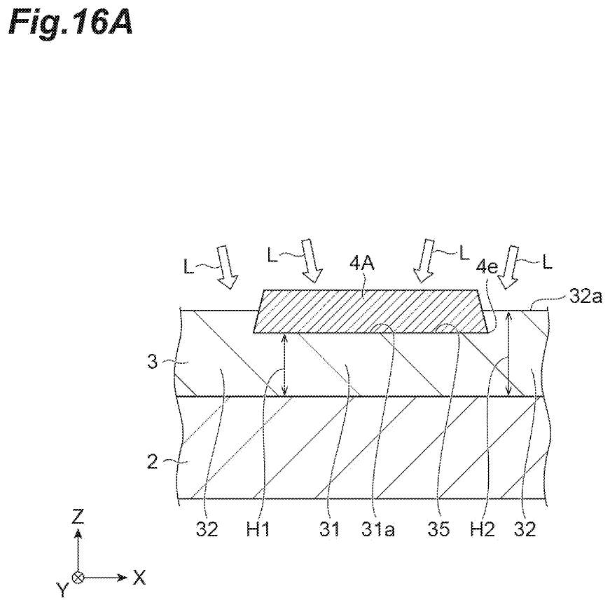

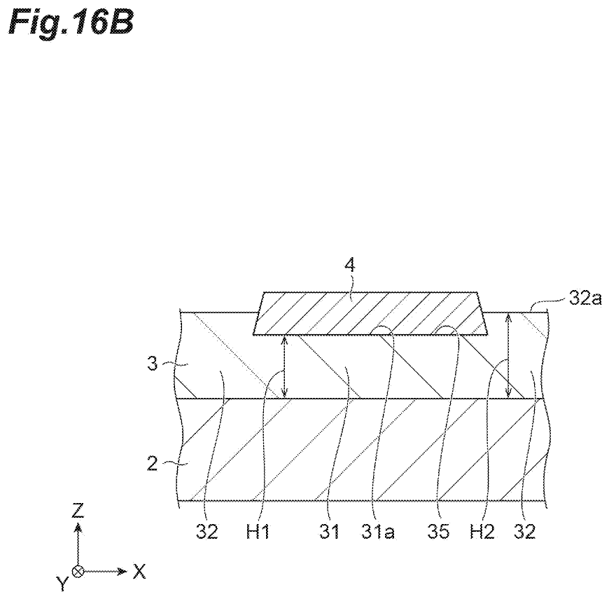

A method for manufacturing the light detection element 1 according to the third embodiment will be described with reference to FIGS. 15A, 15B, 16A, and 16B. First, as illustrated in FIG. 15A, the substrate 2 is prepared. Next, on the main surface 2a of the substrate 2, the underlayer 3 having a single crystal structure is formed with the simple first material containing the first element. In this example, the underlayer 3 is formed of Ge. The underlayer 3 may be formed by a molecular beam epitaxy (MBE) method, a chemical vapor deposition (CVD) method, or a sputtering method.

Subsequently, a light absorbing layer 4A (FIG. 15B) in an amorphous state is formed on the underlayer 3 with the second material that is a compound of the first element and the second element different from the first element. Specifically, first, as illustrated in FIG. 15A, a resist 10 having a plurality of openings 11 (patterns) is formed on the underlayer 3. A method for forming the resist 10 is similar to the method described in the first embodiment.

Next, as illustrated in FIG. 15B, a part of the underlayer 3 corresponding to the plurality of openings 11 of the resist 10 is removed by etching to form the plurality of recesses 35. Subsequently, the plurality of light absorbing layers 4A in the amorphous state is formed, with the second material, on the underlayer 3 on which the resist 10 is formed. In this example, the light absorbing layer 4A is formed by using a sputtering method. At this time, the light absorbing layer 4A is formed not only on the surface of the underlayer 3 exposed from the opening 11 but also on the resist 10. Then, as illustrated in FIG. 16A, the resist 10 is removed (lifted off) together with the light absorbing layer 4A formed on the resist 10, so that the light absorbing layer 4A in the amorphous state having a desired shape is formed on the underlayer 3.

The light absorbing layer 4A is in contact with the surface 31a of the first portion 31. In the Z-axis direction, the height H2 from the main surface 2a of the substrate 2 to the surface 32a of the second portion 32 is greater than a height H1 from the main surface 2a to the surface 31a of the first portion 31. In this state, the light absorbing layer 4A in the amorphous state is heated to form the light absorbing layer 4 having a single crystal structure (FIG. 16B). As in the first embodiment, the light absorbing layer 4A is heated by RTA using light irradiation. As illustrated in FIG. 16A, the light absorbing layer 4A and the underlayer 3 are irradiated with light L, and the light absorbing layer 4A and the underlayer 3 generate heat. In this example, the light absorbing layer 4A is heated to 600 °C or higher.

Subsequently, as illustrated in FIG. 14, a passivation layer 5, a contact region 41, an anode electrode 6, and a cathode electrode 7 are formed. The method for forming the passivation layer 5, the contact region 41, the anode electrode 6, and the cathode electrode 7 is similar to the method described in the first embodiment. Through the above manufacturing process, the light detection element 1 according to the third embodiment is manufactured.

The light detection element 1 according to the present embodiment can also prevent surface roughness of the light absorbing layer 4 and improve detection performance for a reason similar to that of the light detection element 1 according to the first embodiment.

In the present embodiment, a part of the light absorbing layer 4 on the surface 4b side is disposed inside the recess 35, and a part of the light absorbing layer 4 on the surface 4a side is disposed outside the recess 35. Therefore, in the process of manufacturing the light detection element 1, the light absorbing layer 4A in the amorphous state is single-crystallized in a state where a part of the light absorbing layer 4A is disposed in the recess 35 and the other part of the light absorbing layer 4A is exposed from the recess 35. Therefore, crystal efficiency of the single crystal can be improved, and the occurrence of strain and threading dislocations can be suppressed.

The present disclosure is not limited to the above embodiments. Hereinafter, modifications to the embodiments will be described. In the following description, differences from the embodiments will be mainly described, and description of common points may be omitted. For example, in the process of manufacturing the light detection element 1, a protective layer may be formed between the underlayer 3 and the resist 10.

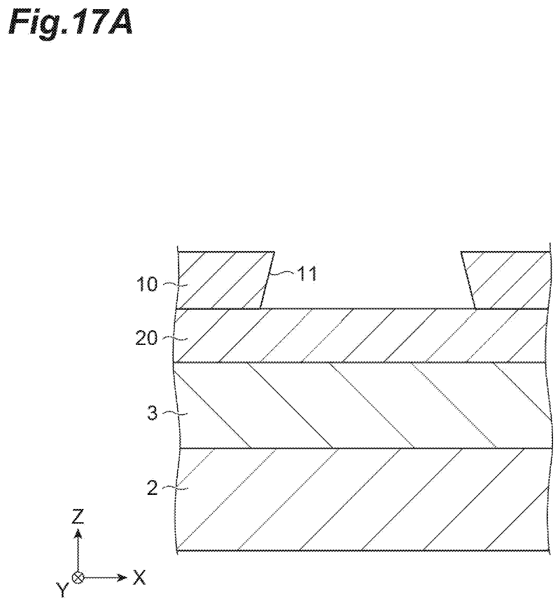

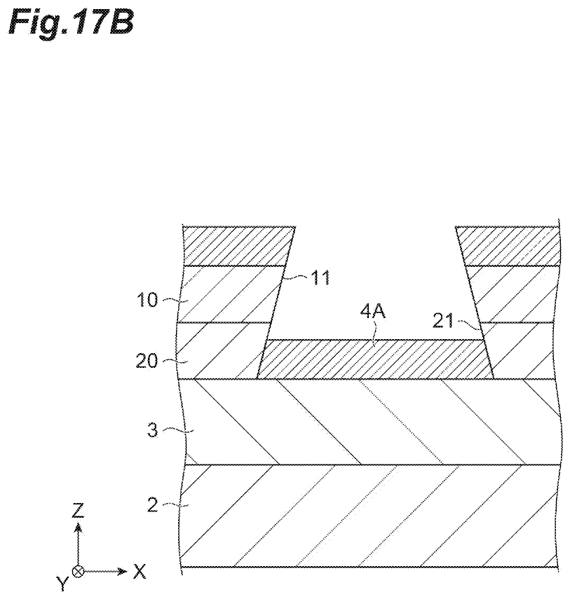

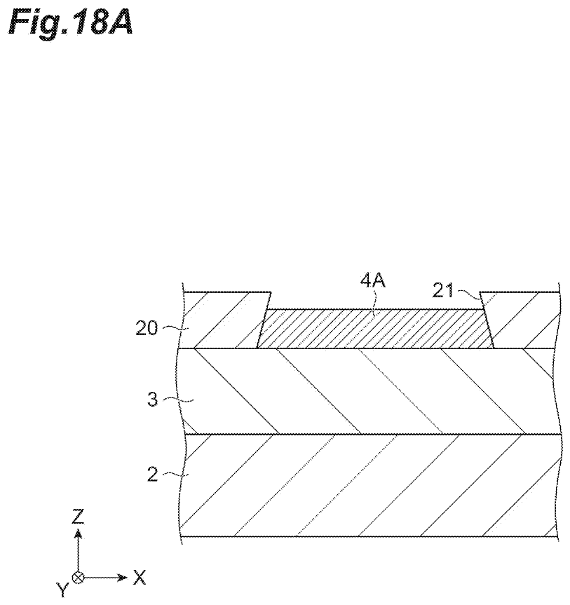

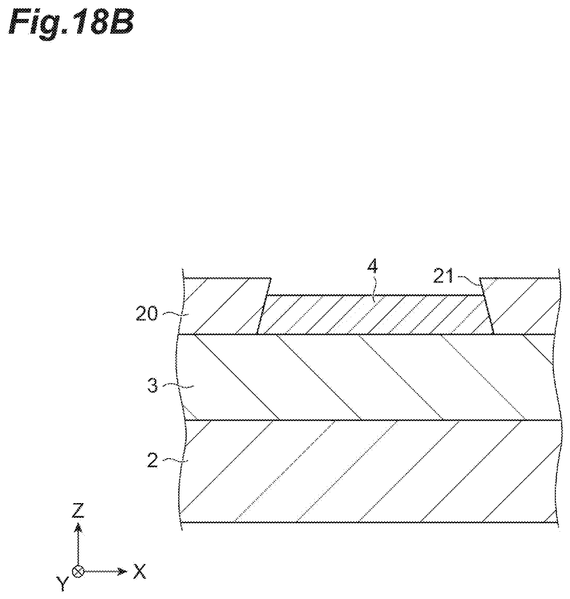

A modification in which a protective film 20 is formed in the process of manufacturing the light detection element 1 according to the first embodiment will be described with reference to FIGS. 17A, 17B, 18A, and 18B. Specifically, as illustrated in FIG. 17A, after the underlayer 3 is formed, the protective film 20 is formed on the underlayer 3. The protective film 20 may be formed of SiN, for example. After the protective film 20 is formed, the resist 10 having the plurality of openings 11 (patterns) is formed. Next, as illustrated in FIG. 17B, etching is performed on the protective film 20 with the resist 10 serving as a mask to remove a part of the protective film 20. This forms a plurality of openings 21 in the protective film 20, and exposes the surface of the underlayer 3 from the openings 21. Then, the light absorbing layer 4A in an amorphous state is formed in the opening 21 of the protective film 20. Next, as illustrated in FIG. 18A, the resist 10 is removed (lifted off) together with the light absorbing layer 4A formed on the resist 10. Then, the light absorbing layer 4A in the amorphous state is heated to form the light absorbing layer 4 having a single crystal structure as illustrated in FIG. 18B. The protective film 20 is formed on the underlayer 3 as in the present modification, which enables the protective film 20 to protect the surface of the underlayer 3.

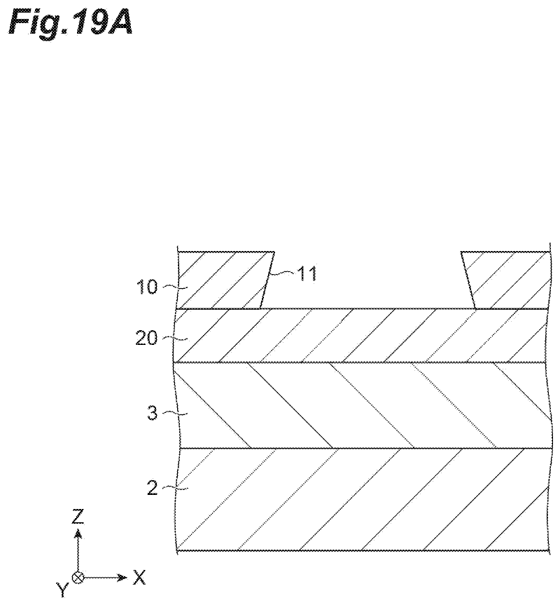

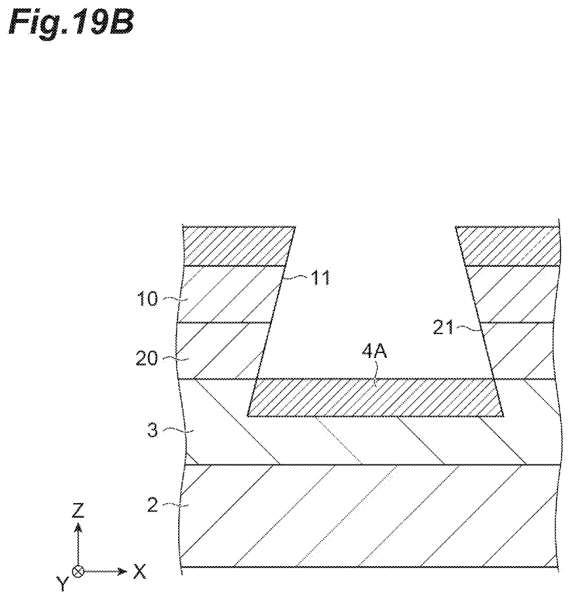

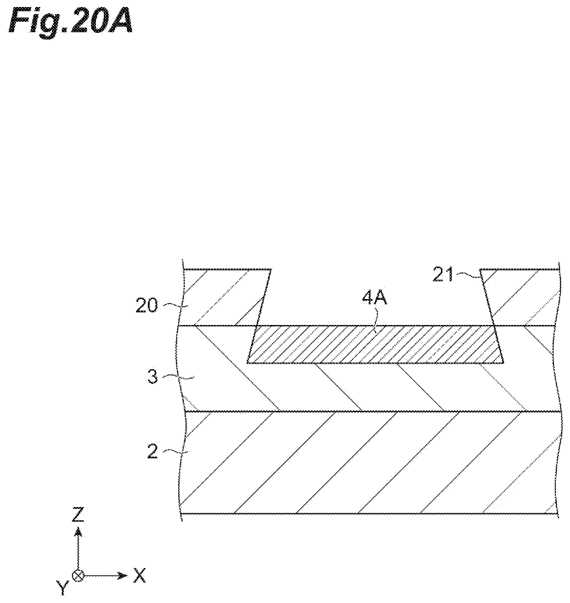

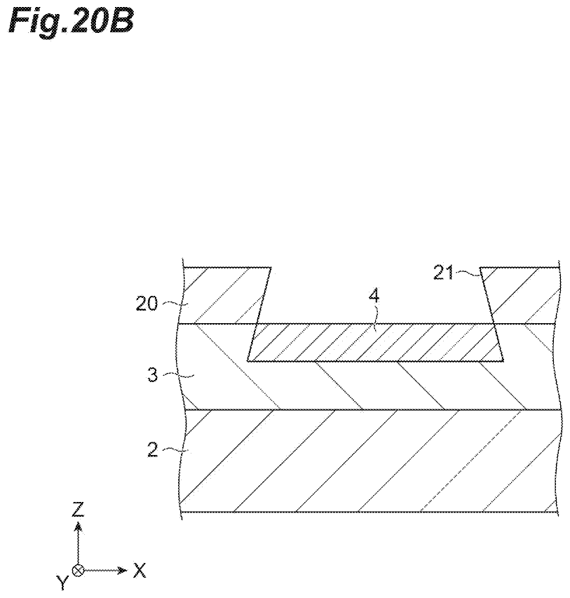

Similarly, the protective film 20 may also be formed in the process of manufacturing the light detection element 1 according to the second embodiment. Specifically, as illustrated in FIG. 19A, after the underlayer 3 is formed, the protective film 20 is formed on the underlayer 3. After the protective film 20 is formed, the resist 10 having the plurality of openings 11 (patterns) is formed. Next, as illustrated in FIG. 19B, etching is performed on the protective film 20 with the resist 10 serving as a mask to remove a part of the protective film 20. This forms a plurality of openings 21 in the protective film 20, and exposes the surface of the underlayer 3 from the openings 21. Then, a part of the underlayer 3 corresponding to the plurality of openings 21 of the protective film 20 is partly removed by etching to form a plurality of recesses. Then, the light absorbing layer 4A in an amorphous state is formed on the underlayer 3. Next, as illustrated in FIG. 20A, the resist 10 is removed (lifted off) together with the light absorbing layer 4A formed on the resist 10. Then, the light absorbing layer 4A in the amorphous state is heated to form the light absorbing layer 4 having a single crystal structure as illustrated in FIG. 20B.

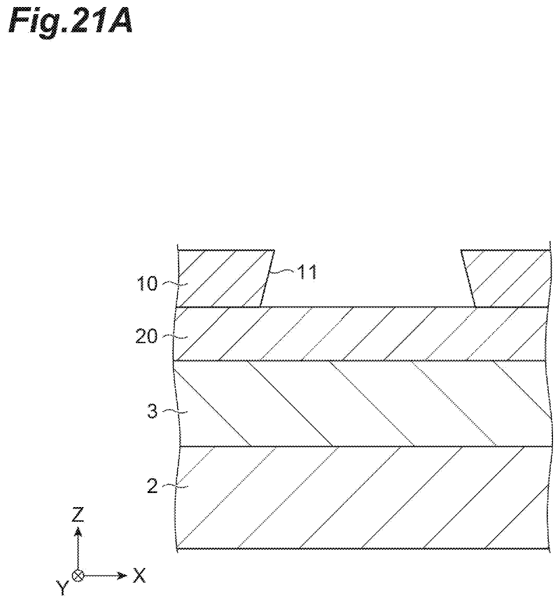

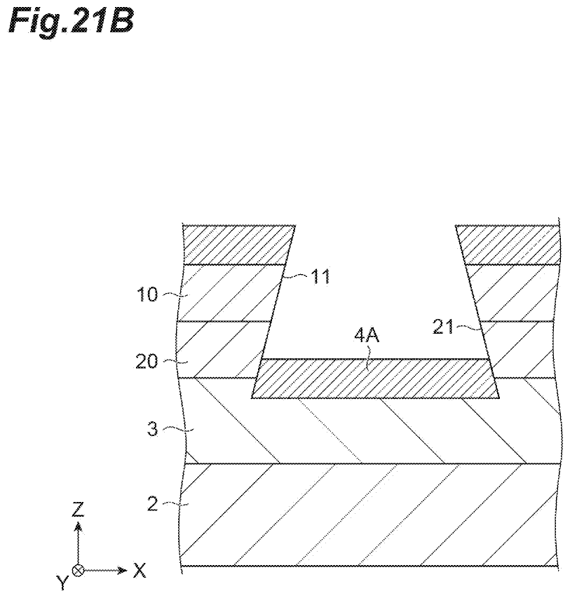

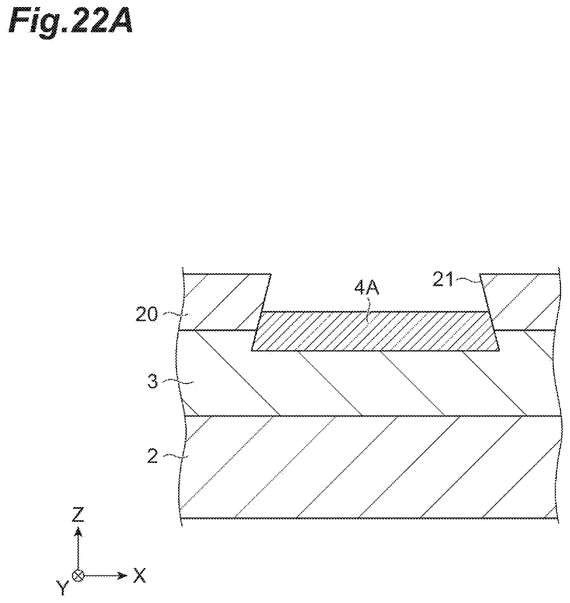

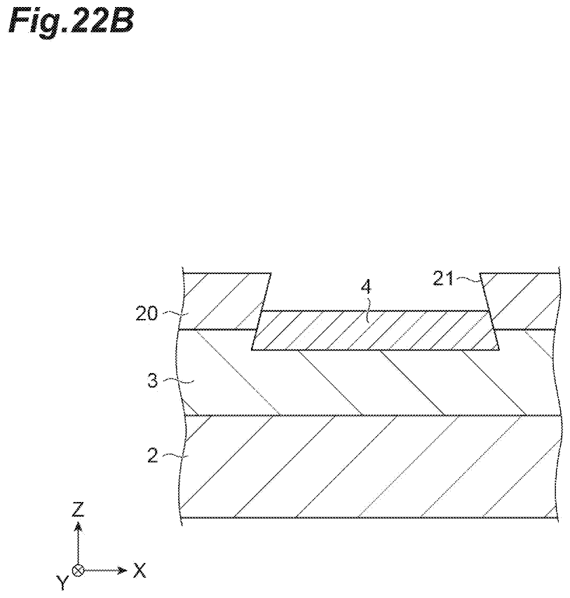

Similarly, the protective film 20 may also be formed in the process of manufacturing the light detection element 1 according to the third embodiment. Specifically, as illustrated in FIG. 21A, after the underlayer 3 is formed, the protective film 20 is formed on the underlayer 3. After the protective film 20 is formed, the resist 10 having the plurality of openings 11 (patterns) is formed. Next, as illustrated in FIG. 21B, etching is performed on the protective film 20 with the resist 10 serving as a mask to remove a part of the protective film 20. This forms a plurality of openings 21 in the protective film 20, and exposes the surface of the underlayer 3 from the openings 21. Then, a part of the underlayer 3 corresponding to the plurality of openings 21 of the protective film 20 is partly removed by etching to form a plurality of recesses. Then, the light absorbing layer 4A in an amorphous state is formed on the underlayer 3. Next, as illustrated in FIG. 22A, the resist 10 is removed (lifted off) together with the light absorbing layer 4A formed on the resist 10. Then, the light absorbing layer 4A in the amorphous state is heated to form the light absorbing layer 4 having a single crystal structure as illustrated in FIG. 22B.

In the embodiments described above, the light detection element 1 includes the plurality of light absorbing layers 4, but the number of light absorbing layers 4 is not limited. That is, the light detection element 1 may include only one light absorbing layer 4. Each of the first element and the second element may be an element other than the group 14 element. The first element may be an element other than Ge. The second element may be an element other than Sn. For example, the second element may be Si.

In the process of manufacturing the light detection element 1, after the light absorbing layer 4 having a single crystal structure is formed, a part of the underlayer 3 may be removed by etching or the like. For example, at least a part of the second portion 32 of the underlayer 3 may be removed to form a mesa structure including the light absorbing layer 4 and the underlayer 3. The second portion 32 may be removed to such an extent that the main surface 2a of the substrate 2 is not exposed, or may be removed to such an extent that the main surface 2a is exposed.

The shape of the light absorbing layer 4 is not limited. For example, the light absorbing layer 4 may have a square shape when viewed in the Z-axis direction. The size of the light absorbing layer 4 is not limited. For example, the width W1 of the light absorbing layer 4 in the X-axis direction may be larger than 4 mm.

In the step of forming the light absorbing layer 4 having a single crystal structure by heating the light absorbing layer 4A in the amorphous state, the heating temperature of the light absorbing layer 4A may be set according to the composition of the light absorbing layer 4A (for example, the concentration of Sn contained). For example, the light absorbing layer 4A may be heated to a predetermined temperature of lower than 600 °C.

What is claimed is:

1. A light detection element comprising:
a substrate having a main surface;
an underlayer formed, on the main surface, of a simple first material containing a first element and having a single crystal structure; and
a light absorbing layer having a single crystal structure formed, on the underlayer, of a second material that is a compound of the first element and a second element different from the first element, wherein
the underlayer includes a first portion located between the substrate and the light absorbing layer, and a second portion located outside the light absorbing layer and adjacent to the first portion when viewed in a thickness direction of the substrate,
the light absorbing layer is in contact with a first surface of the first portion on a side opposite to the substrate, and
in the thickness direction of the substrate, a height from the main surface to a second surface of the second portion opposite to the substrate is equal to or greater than a height from the main surface to the first surface.

2. The light detection element according to claim 1, wherein
in the thickness direction of the substrate, the height from the main surface to the second surface is greater than the height from the main surface to the first surface.

3. The light detection element according to claim 1, wherein
the light absorbing layer has a side surface connecting a surface of the light absorbing layer on a side opposite to the substrate and a surface of the light absorbing layer on a side of the substrate, and
the second portion is in contact with the side surface.

4. The light detection element according to claim 1, wherein
the first element is a group 14 element, and
the second element is a group 14 element different from the first element.

5. The light detection element according to claim 1, wherein
the first element is Ge, and
the second element is Sn.

6. The light detection element according to claim 1, comprising
a pair of second portions, the second portions are each being the second portion, wherein
the pair of second portions is located so as to sandwich the first portion in a direction intersecting the thickness direction of the substrate.

7. The light detection element according to claim 1, comprising
a plurality of light absorbing layers, the light absorbing layers are each being the light absorbing layer, wherein
the plurality of light absorbing layers is arranged apart from each other in a direction intersecting the thickness direction of the substrate.

8. A method for manufacturing a light detection element, comprising:
a step of preparing a substrate having a main surface;
a step of forming an underlayer having a single crystal structure with a simple first material containing a first element on the main surface;
a step of forming a light absorbing layer in an amorphous state on the underlayer with a second material that is a compound of the first element and a second element different from the first element; and
a step of forming a light absorbing layer having a single crystal structure by heating the light absorbing layer in the amorphous state, wherein
in the step of forming the light absorbing layer having the single crystal structure,
the underlayer includes a first portion located between the substrate and the light absorbing layer in the amorphous state, and a second portion located outside the light absorbing layer in the amorphous state and adjacent to the first portion when viewed in a thickness direction of the substrate,
the light absorbing layer is in contact with a first surface of the first portion on a side opposite to the substrate, and
the light absorbing layer in the amorphous state is heated in a state in which, in the thickness direction of the substrate, a height from the main surface to a second surface of the second portion opposite to the substrate is equal to or greater than a height from the main surface to the first surface.
